(19) United States
(12) Patent Application Publication
(10) Pub. No.: US 2012/0068736 A1
(43) Pub. Date: Mar. 22, 2012

(54) DESIGN APPARATUS, DESIGN METHOD AND SEMICONDUCTOR INTEGRATED CIRCUIT

(75) Inventor: Atsushi MASUDA, Kanagawa (JP)

(73) Assignee: KABUSHIKI KAISHA TOSHIBA, Tokyo (JP)

(21) Appl. No.: 13/032,506

(22) Filed: Feb. 22, 2011

(30) Foreign Application Priority Data
Sep. 22, 2010 (JP) 2010-212529

(51) Int. Cl. H03K 19/096; G06F 17/50; G06F 9/455

(52) U.S. Cl. 326/93; 716/108

(57) ABSTRACT

A design apparatus according to the present embodiment includes a scheduling section, a group ID assigning section, a transition violation detecting section and a state inserting section. The scheduling section generates a plurality of states that transition based on a clock according to a control data flow graph generated from a behavioral description and common resource schedule information. The group ID assigning section assigns group IDs to the plurality of states under a predetermined condition. The transition violation detecting section detects whether or not there is any transition violation among the plurality of states to which the group IDs are assigned. The state inserting section adds, when a transition violation is detected by the transition violation detecting section, a new state between states from which the transition violation has been detected.

### CROSS-REFERENCE TO RELATED APPLICATION

This application is based upon and claims the benefit of priority from the prior Japanese Patent Application No. 2010-212529 filed on Sep. 22, 2010; the entire contents of which are incorporated herein by reference.

### FIELD

An embodiment described herein relate generally to a design apparatus, a design method and a semiconductor integrated circuit.

### BACKGROUND

Conventionally, design apparatuses which design a logic circuit written in RTL (Register Transfer Level) from a behavioral description written in a software description language or the like are known. When designing a semiconductor integrated circuit that shares a common resource such as pipeline functional unit, RAM or ROM among two or more different logic circuits designed in this way, the different logic circuits cannot use the common resource at the same time (cycle), and therefore time zones in which the resource is used need to be differentiated from each other.

For that purpose, it is necessary to design an arbitration circuit and incorporate the designed arbitration circuit in each of the different logic circuits. By causing the arbitration circuits incorporated in the different logic circuits to communicate with each other, the design apparatus is designed to prevent the different logic circuits from using the common resource in the same time zone.

However, when the arbitration circuits are incorporated in the different logic circuits to communicate with each other, if, for example, two logic circuits try to use the common resource simultaneously, one logic circuit needs to wait for operation. The operation of the logic circuit is interrupted, and therefore when the operation is resumed, the operation may not be performed normally. In such a case, there is a problem that the logic circuit needs to be redesigned.

Furthermore, the operation of the logic circuit is interrupted in the arbitration portion, there is no guarantee that the logic circuit operates normally, and a new logical verification needs to be conducted, resulting in a problem that even when design data of the existing design is reused, the design period cannot be shortened.

Furthermore, since it is necessary to newly verify whether or not the common resource is shared correctly, new testing data needs to be provided, resulting in another problem that the design period is extended more and more.

Thus, it has been conventionally difficult to design a logic circuit that shares a common resource without providing any arbitration circuit in the logic circuit.

### BRIEF DESCRIPTION OF THE DRAWINGS

FIG. 1 is a diagram illustrating a configuration of an information processing system according to an embodiment of the present invention;

FIG. 2 is a diagram illustrating a configuration of a design apparatus according to the present embodiment;

FIG. 3 is a diagram illustrating an example of common resource schedule information;

FIG. 4 is a diagram illustrating an example of a state transition machine;

FIG. 5 is a diagram illustrating an example of a state transition machine to which group IDs are assigned;

FIG. 6 is a diagram illustrating an example of a state transition machine to which a new state is added;

FIG. 7 is a flowchart illustrating an example of design processing by a design apparatus;

FIG. 8 is a block diagram illustrating a configuration of a semiconductor integrated circuit according to the present embodiment;

FIG. 9 is a block diagram illustrating another configuration example of the semiconductor integrated circuit;

FIG. 10 is a block diagram illustrating a further configuration example of the semiconductor integrated circuit; and

FIG. 11 is a block diagram illustrating a configuration of a semiconductor integrated circuit in which three logic circuits use a common resource.

### DETAILED DESCRIPTION

A design apparatus of the present embodiment includes a scheduling section, a group ID assigning section, a transition violation detecting section and a state inserting section. The scheduling section generates a plurality of states that transition based on a clock according to a control data flow graph generated from a behavioral description and common resource schedule information. The group ID assigning section assigns group IDs to the plurality of states under a predetermined condition. The transition violation detecting section detects whether or not there is any transition violation among the plurality of states to which group IDs are assigned. When the transition violation detecting section detects a transition violation, the state inserting section adds a new state between states from which the transition violation has been detected.

Hereinafter, an embodiment of the present invention will be described in detail with reference to the accompanying drawings.

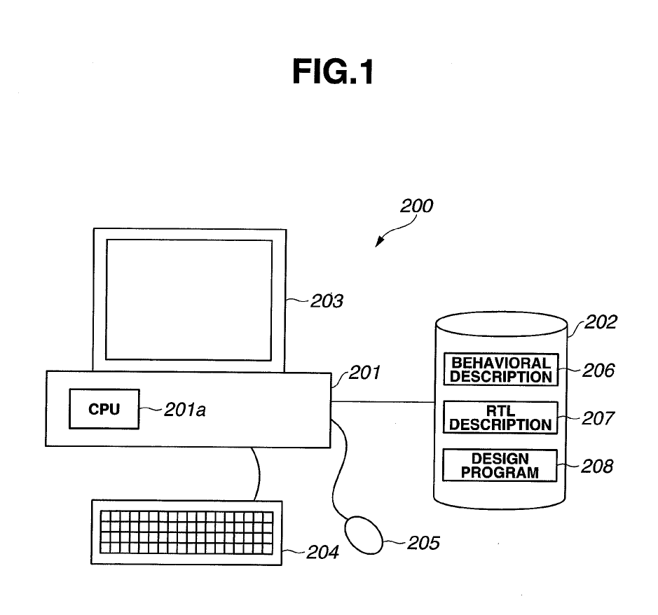

First, a configuration of an information processing system according to the present embodiment will be described based on FIG. 1.

FIG. 1 is a diagram illustrating a configuration of the information processing system according to the present embodiment.

As shown in FIG. 1, an information processing system 200 is configured by including a main unit 201, a storage apparatus 202 that stores various kinds of data and a display apparatus 203 that displays various kinds of data. The main unit 201 is a computer main unit such as a personal computer and is mounted with a CPU 201a and a main memory (not shown) or the like. Furthermore, the main unit 201 is connected with a keyboard 204 and a mouse 205 as input devices. The main unit 201 executes various programs based on commands from these input devices.

The storage apparatus 202 stores a behavioral description 206 written in a software description language or the like, an RTL description 207 generated from the behavioral description 206 and a design program 208 including a program that has a function of generating the RTL description 207 from the behavioral description 206.

Using the keyboard 204 and the mouse 205, a user inputs the behavioral description 206 written in a software description language or the like, executes the design program 208 on the main unit 201, and can thereby obtain the RTL description 207. Thus, the main unit 201 that can execute the design program 208 constitutes a design apparatus 1 of the present embodiment which will be described later. The behavioral description 206 and the RTL description 207 may be stored in the storage apparatus 202 or stored in another storage medium.

Here, the configuration of the design apparatus 1 configured as shown above will be described.

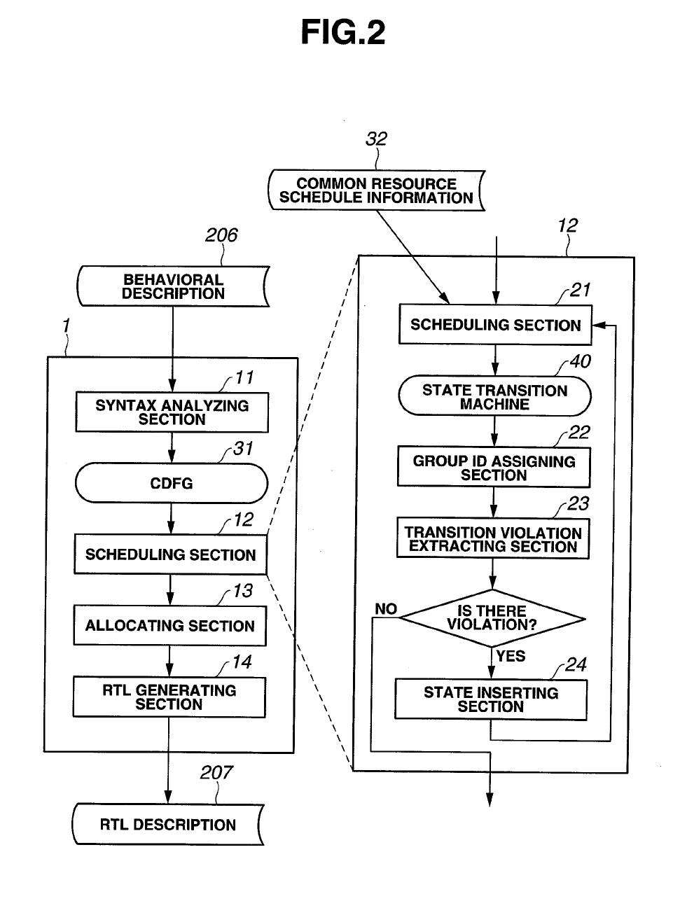

FIG. 2 is a diagram illustrating a configuration of the design apparatus according to the present embodiment.

As shown in FIG. 2, the design apparatus 1 is configured by including a syntax analyzing section 11, a scheduling section 12, an allocating section 13 and an RTL generating section 14. In the present embodiment, the scheduling section 12 is configured to be expanded. That is, the scheduling section 12 is configured by including a scheduling section 21, a group ID assigning section 22, a transition violation extracting section 23 and a state inserting section 24.

The behavioral description 206 is inputted to the syntax analyzing section 11. The syntax analyzing section 11 analyzes a syntax of the description of the behavioral description 206 and generates a control data flow graph (hereinafter referred to as “CDFG”) 31. The CDFG 31 generated by the syntax analyzing section 11 is supplied to the scheduling section 21. Furthermore, common resource schedule information 32 is supplied to the scheduling section 21.

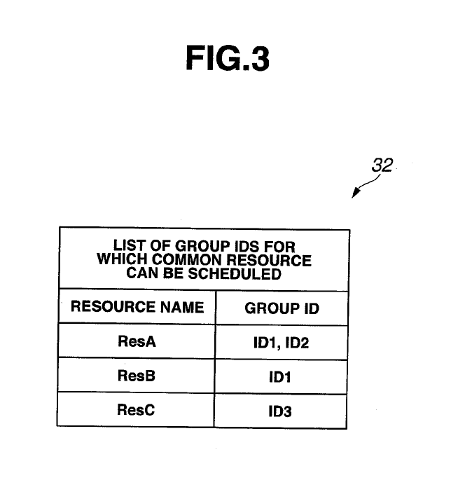

FIG. 3 is a diagram illustrating an example of common resource schedule information.

The common resource schedule information 32 is information for linking a common resource, which will be described later, with a group ID. As shown in FIG. 3, the common resource schedule information 32 is information associated with a group ID in a state that may be scheduled for each common resource.

The scheduling section 21 performs scheduling processing according to the CDFG 31 and the common resource schedule information 32 and generates a state transition machine 40.

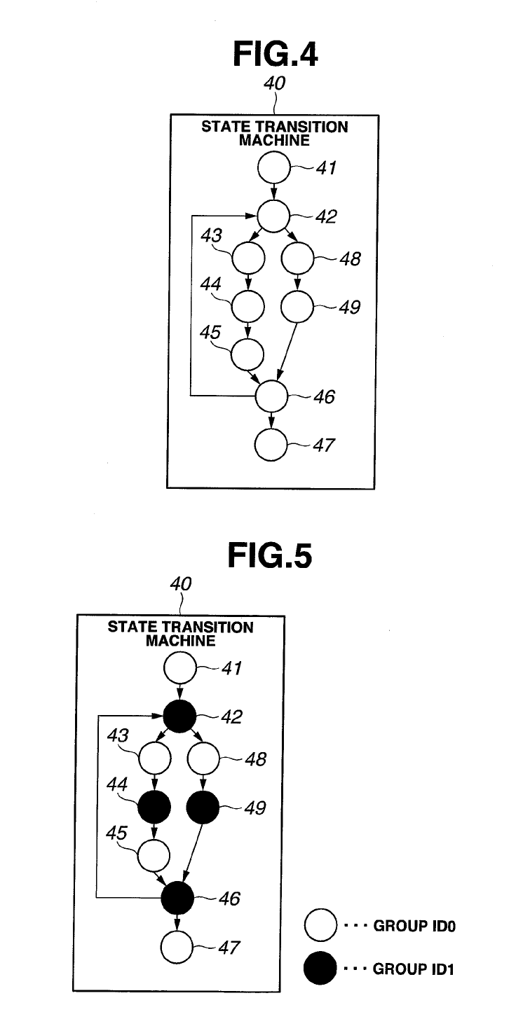

FIG. 4 is a diagram illustrating an example of the state transition machine.

As shown in FIG. 4, the state transition machine 40 includes a plurality of states 41 to 49. In the example in FIG. 4, suppose a first state is a state 41 and a state to which the state 41 transitions is a state 42. Next, suppose one state that branches from the state 42 according to a branch condition is a state 43 and states to which the state 43 sequentially transitions are states 44 to 47. Suppose the other state that branches from the state 42 is a state 48 and a state to which the state 48 transitions is a state 49. Furthermore, the state 46 transitions to the state 42 or the state 47 according to a branch condition. The plurality of states 41 to 49 change in every one cycle of a clock signal.

The group ID assigning section 22 assigns group IDs to the states 41 to 49 of the state transition machine 40 under a predetermined condition. Here, the group ID assigning section 22 assigns group IDs in such a way that a transition takes place from a state having a certain group ID only to a state having a predetermined group ID. For example, a transition destination of a state having a group ID of 0 is a state having a group ID of 1 and a transition destination of a state having a group ID of 1 is a state having a group ID of 0. FIG. 5 shows the state transition machine 40 in which group IDs are assigned by the group ID assigning section 22 in such a way.

FIG. 5 is a diagram illustrating an example of the state transition machine in which group IDs are assigned.

As shown in FIG. 5, the group ID assigning section 22 assigns group ID0 to the first state 41 and assigns group ID1 to the state 42 which is the transition destination from the state 41. Next, the group ID assigning section 22 assigns group ID0 to the states 43 and 48 which are transition destinations from the state 42. Through similar procedures, the group ID assigning section 22 assigns group ID1 to the states 44, 46 and 49 and assigns group ID0 to the states 45 and 47. In the example in FIG. 5, among the states 41 to 49, states having a group ID of 0 are expressed by white circles and states having a group ID of 1 are expressed by black circles.

The transition violation extracting section 23 extracts transition violations of the state transition machine 40 in which group IDs are assigned in this way. As described above, group IDs are assigned to the states 41 to 49 so that a transition takes place from group ID0 to group ID1 and a transition takes place from group ID1 to group ID0, but in the example in FIG. 5, transition violations have occurred at two locations. The transition from the state 49 to the state 46 and the transition from the state 46 to the state 42 are transitions from group ID1 to group ID1, which constitute transition violations. Thus, the transition violation extracting section 23 extracts the transition from the state 49 to the state 46 and the transition from the state 46 to the state 42 as transition violations.

Thus, when the state 49 of the transition source and the state 46 of the transition destination have the same group ID, the transition violation extracting section 23 extracts the transition as a transition violation. Likewise, since the state 46 of the transition source and the state 42 of the transition destination have the same group ID, the transition violation extracting section 23 extracts the transition as a transition violation.

When the transition violation extracting section 23 extracts a transition violation of the state transition machine 40, the state inserting section 24 adds a new state between states from which the transition violation is extracted, here, between the state 49 and the state 46 and between the state 46 and the state 42 respectively to resolve the transition violation.

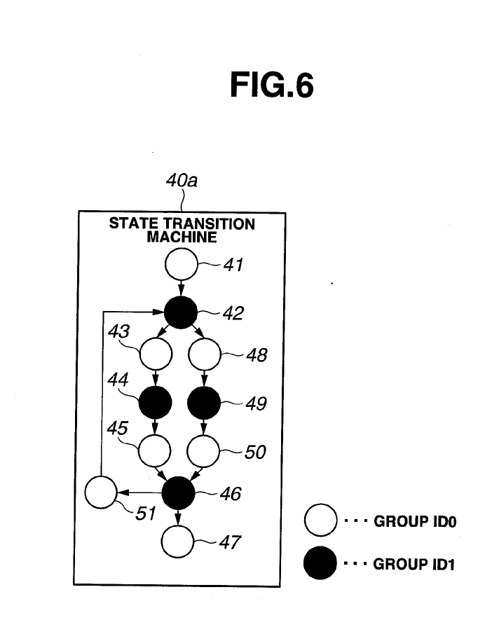

FIG. 6 is a diagram illustrating an example of the state transition machine with new states added. Suppose the state transition machine 40 with new states added is a “state transition machine 40a.”

As shown in FIG. 6, a state 50 having a group ID of 0 is newly added between the state 49 and the state 46 by the state inserting section 24. Likewise, a state 51 having a group ID of 0 is newly added between the state 46 and the state 42 by the state inserting section 24. When the new states 50 and 51 are added by the state inserting section 24, the process returns to the scheduling section 21 to repeat similar processing. Thus, group ID0 is assigned to the newly added states 50 and 51 by the group ID assigning section 22. When the transition violation extracting section 23 determines that there is no transition violation, the state transition machine 40a is outputted to the allocating section 13.

The allocating section 13 performs allocation processing on the inputted state transition machine 40a and allocates a common resource to be shared. In this case, the allocating section 13 allocates a common resource only to states having a specific group ID. For example, the allocating section 13 allocates a common resource 102 to be shared so as to be used only in a state having a group ID of 1.

The RTL generating section 14 generates the RTL description 207 using data after allocation processing. In this way, a logic circuit using a common resource shared only in a state having a group ID of 1 is designed.

Here, design processing by the design apparatus 1 configured as shown above will be described.

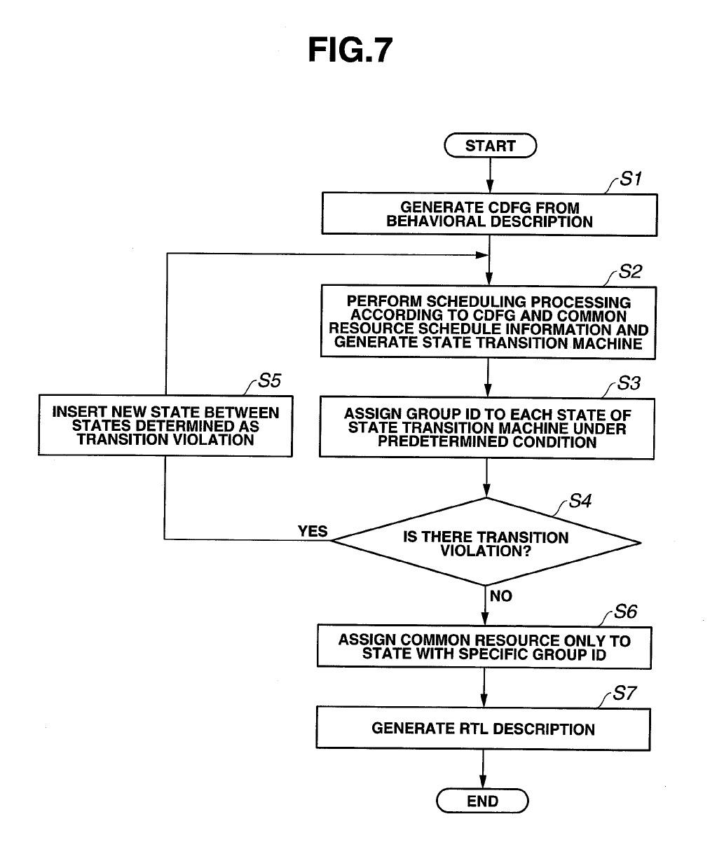

FIG. 7 is a flowchart illustrating an example of design processing by the design apparatus.

First, a syntax analysis of the behavioral description 206 is performed and the CDFG 31 is generated (step S1). Scheduling processing is performed according to the CDFG 31 and the common resource schedule information 32, and a state transition machine is generated (step S2). Next, a group ID is assigned to each state of the state transition machine under a predetermined condition (step S3). Next, it is determined whether or not there is any transition violation in the state in which the group ID is assigned (step S4). When there is a transition violation, the determination result is YES and a new state is inserted between the states determined as the transition violation (step S5), the process returns to step S2 and repeats similar processing. On the other hand, when there is no transition violation, the determination result is NO and a common resource is assigned only to states having a specific group ID (step S6). Finally, the RTL description 207 is generated (step S7) and the process ends.

A case has been described above where a logic circuit using a common resource to be shared only in states having a group ID of 1 is designed, but a similar procedure is used to design a state transition machine and design a logic circuit using a common resource to be shared only in states having a group ID of 0. A plurality of logic circuits designed in this way are then combined with a common resource. This allows the user to design a semiconductor integrated circuit in which a common resource is shared between a logic circuit using the common resource to be shared only in states having a group ID of 1 and a logic circuit using the common resource to be shared only in states having a group ID of 0. Here, a semiconductor integrated circuit designed in this way will be described.

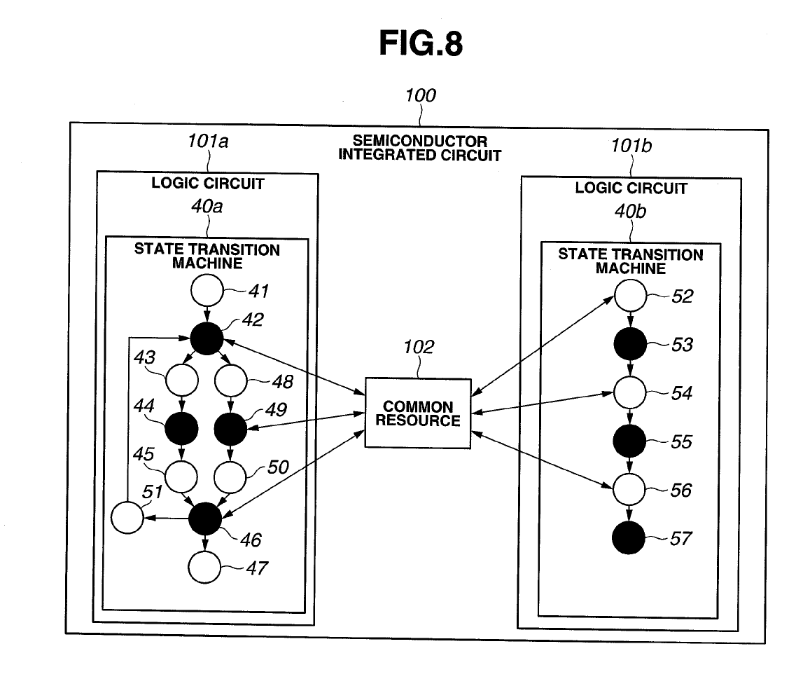

FIG. 8 is a block diagram illustrating a configuration of a semiconductor integrated circuit according to the present embodiment.

As shown in FIG. 8, a semiconductor integrated circuit 100 is configured by including a plurality of (here two) logic circuits 101a and 101b and a common resource 102.

The logic circuits 101a and 101b include state transition machines 40a and 40b which constitute control sections of the logic circuits 101a and 101b.

The state transition machines 40a and 40b include a plurality of states 41 to 51 and states 52 to 57 respectively, change their states in every one cycle of a clock signal and control the logic circuits 101a and 101b in the respective states.

The logic circuit 101a has the state transition machine 40a shown in FIG. 6 and uses, that is, accesses a common resource 102 to be shared only in states having a group ID of 1. On the other hand, the state transition machine 40b of the logic circuit 101b is designed to use, that is, access the common resource 102 to be shared only in states having a group ID of 0. Therefore, the logic circuit 101a uses the common resource 102 to be shared only in states having a group ID of 1 and the logic circuit 101b uses the common resource 102 to be shared only in states having a group ID of 0.

That is, when an initial cycle is assumed to be a first cycle, the state 52 of the state transition machine 40b uses the common resource 102 in the first cycle and the state 42 of the state transition machine 40a uses the common resource 102 in a second cycle. Similarly, in a third cycle, the state 54 of the state transition machine 40b uses the common resource 102, and in a fourth cycle, the state 44 or state 49 of the state transition machine 40a uses the common resource 102 according to a branch condition.

In the semiconductor integrated circuit 100 configured as shown above, the logic circuit 101a uses the common resource 102 only in an even-numbered cycle and the logic circuit 101b uses the common resource 102 only in an odd-numbered cycle, that is, the logic circuit 101a and the logic circuit 101b are designed to use the common resource 102 exclusively. Thus, the semiconductor integrated circuit 100 allows the common resource 102 to be shared between the different logic circuits 101a and 101b without any arbitration circuit.

Furthermore, since the common resource 102 can be shared between the logic circuits 101a and 101b designed in this way without any arbitration circuit, there is no necessity for new verification work and a design period for the logic circuits can be shortened.

Furthermore, operations of the logic circuits 101a and 101b of the semiconductor integrated circuit 100 are independent of each other, that is, operations are never interrupted, and therefore the operations before and after the sharing are the completely same and there is no necessity for any particular verification work even after the connection.

Furthermore, although the logic circuit 101a and the logic circuit 101b share the common resource 102 using different group IDs, shifting the cycle to start operation by one cycle may also allow the common resource to be shared between different logic circuits that share the common resource 102 using the same group ID.

Furthermore, although a case has been described in the present embodiment where the logic circuits 101a and 101b are designed individually and then combined together, if a plurality of logic circuits designed according to the present embodiment are saved, even when the common resource 102 is shared, it is also possible to freely combine logic circuits among the designed logic circuits according to the purpose of use and realize an operation as a whole.

In the states 41 to 51 of the state transition machine 40a, a state of group ID0 and a state of group ID1 are assigned in every one cycle, but assignment is not limited to this. For example, the design apparatus 1 may also be used to generate a logic circuit having a state transition machine with a state of group ID0 and a state of group ID1 assigned in every two cycles or a logic circuit having a state transition machine with a state of group ID0 assigned in two cycles and then a state of group ID1 assigned in one cycle. The logic circuits generated in this way may be combined to thereby design the following semiconductor integrated circuit.

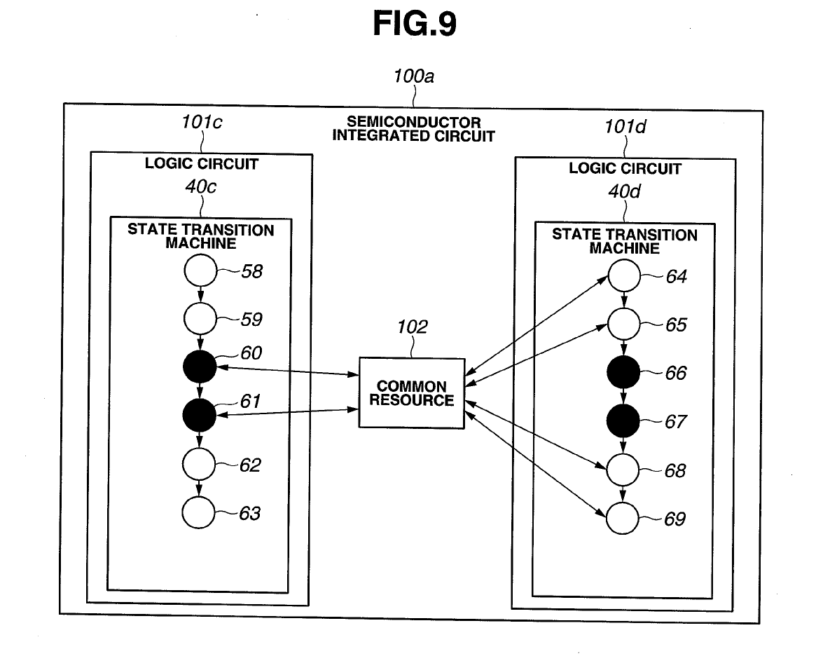

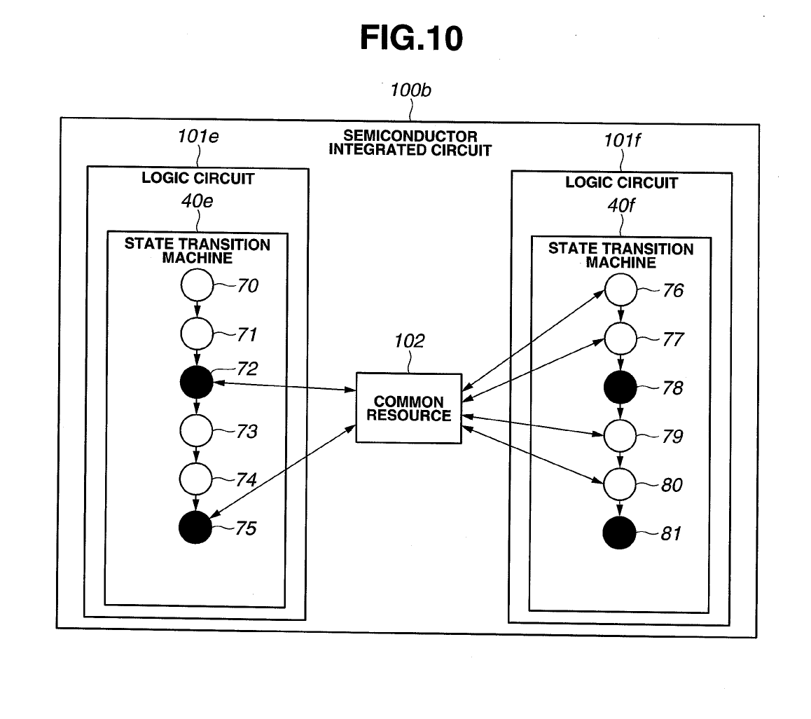

FIG. 9 and FIG. 10 are block diagrams illustrating other configuration examples of the semiconductor integrated circuit. In FIG. 9 and FIG. 10, components similar to those in FIG. 8 will be assigned the same reference numerals and descriptions thereof will be omitted.

A semiconductor integrated circuit 100a shown in FIG. 9 is configured by including logic circuits 101c and 101d and a common resource 102.

The logic circuits 101c and 101d include state transition machines 40c and 40d respectively. The state transition machine 40c is configured by including a plurality of states 58 to 63 and the state transition machine 40d is configured by including a plurality of states 64 to 69. The states 58 to 63 of the state transition machine 40c and the states 64 to 69 of the state transition machine 40d are designed such that a group ID transitions in every two cycles.

The state transition machine 40c is designed to use the common resource 102 to be shared only in states having a group ID of 1 and the state transition machine 40d is designed to use the common resource 102 to be shared only in states having a group ID of 0.

Thus, the state transition machine 40c shares the common resource 102 in states 60 and 61 having a group ID of 1 and the state transition machine 40d shares the common resource 102 in states 64, 65, 68 and 69 having a group ID of 0.

As a result, the logic circuits 101c and 101d use the common resource 102 in every predetermined number of clocks, here two clocks.

The semiconductor integrated circuit 100a configured in this way allows the common resource 102 to be shared between the different logic circuits 101c and 101d without any arbitration circuit in the same way as in the semiconductor integrated circuit 100 in FIG. 8.

On the other hand, a semiconductor integrated circuit 100b shown in FIG. 10 is configured by including logic circuits 101e and 101f and a common resource 102.

The logic circuits 101e and 101f include state transition machines 40e and 40f respectively. The state transition machine 40e is configured by including a plurality of states 70 to 75 and the state transition machine 40f is configured by including a plurality of states 76 to 81. The states 70 to 75 of the state transition machine 40e and the states 76 to 81 of the state transition machine 40f are designed respectively such that states having a group ID of 0 are assigned in two cycles and states having a group ID of 1 are then assigned in one cycle.

The state transition machine 40e is designed to use the common resource 102 to be shared only in states having a group ID of 1 and the state transition machine 40f is designed to use the common resource 102 to be shared only in states having a group ID of 0.

Thus, the state transition machine 40e shares the common resource 102 in states 72 and 75 having a group ID of 1 and the state transition machine 40f shares the common resource 102 in states 76, 77, 79 and 80 having a group ID of 0.

As a result, the logic circuits 101e and 101f use the common resource 102 with different frequencies.

The semiconductor integrated circuit 100b configured as shown above allows the common resource 102 to be shared between the different logic circuits 101e and 101f without any arbitration circuit in the same way as in the semiconductor integrated circuit 100 in FIG. 8.

Furthermore, the logic circuit 101e uses the common resource 102 once in every three cycles and the logic circuit 101f uses the common resource 102 twice in every three cycles. Thus, the semiconductor integrated circuit 100b is effective when the different logic circuits 101e and 101g use the common resource 102 with different frequencies.

Furthermore, the present embodiment has described a case where two logic circuits; logic circuits 101a and 101b in the example in FIG. 8, use the common resource 102, but a configuration may also be adopted in which three or more logic circuits use the common resource 102. Hereinafter, a semiconductor integrated circuit in which three logic circuits use a common resource will be described.

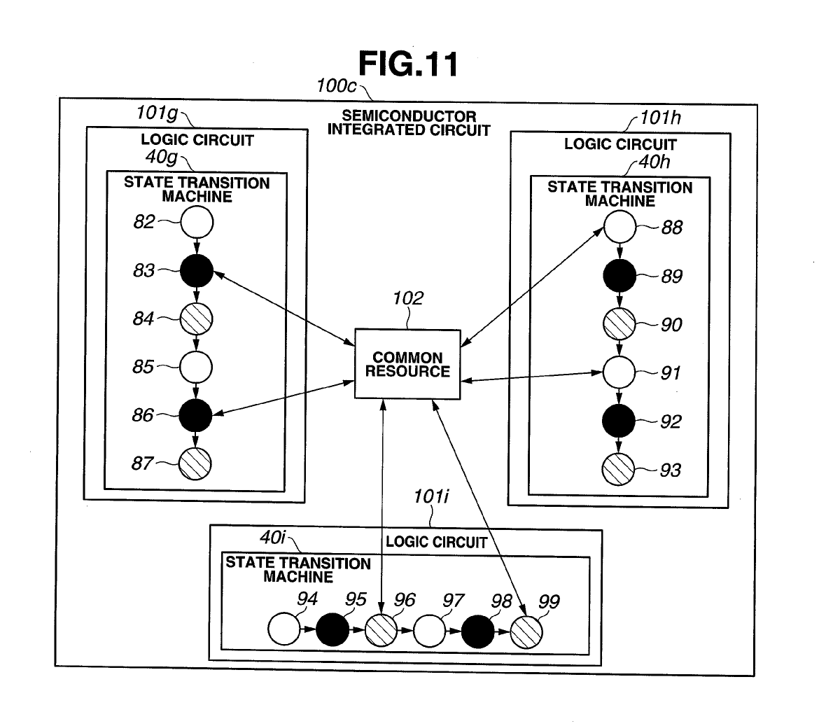

FIG. 11 is a block diagram illustrating a configuration of a semiconductor integrated circuit in which three logic circuits use a common resource.

As shown in FIG. 11, a semiconductor integrated circuit 100c is configured by including three logic circuits 101g, 101h and 101i and a common resource 102.

The logic circuits 101g, 101h and 101i include state transition machines 40g, 40h and 40i respectively. The state transition machine 40g is configured by including a plurality of states 82 to 87, the state transition machine 40h is configured by including a plurality of states 88 to 93 and the state transition machine 40i is configured by including a plurality of states 94 to 99.

The states 82 to 87 of the state transition machine 40g are designed to transition from a state having a group ID of 0 to a state having a group ID of 1, from a state having a group ID of 1 to a state having a group ID of 2 and from a state having a group ID of 2 to a state having a group ID of 0. That is, group ID0 is assigned to the first state 82 of the state transition machine 40g and group ID1 is assigned to the state 83 which is the transition destination from the state 82. Next, group ID2 is assigned to the state 84 which is the transition destination from the state 83 and group ID0 is assigned to the state 85 which is the transition destination from the state 84. In the states 82 to 87, states having a group ID of 0 are expressed by white circles, states having a group ID of 1 are expressed by black circles and states having a group ID of 2 are expressed by shaded circles. Furthermore, the state transition machines 40h and 40i are also designed in the same way as the state transition machine 40g.

The state transition machine 40g is designed to use the common resource 102 to be shared only in states having a group ID of 1, the state transition machine 40h is designed to use the common resource 102 to be shared only in states having a group ID of 0 and the state transition machine 40i is designed to use the common resource 102 to be shared only in states having a group ID of 2.

Thus, the state transition machine 40g shares the common resource 102 in the states 83 and 86 having a group ID of 1, the state transition machine 40h shares the common resource 102 in the states 88 and 91 having a group ID of 0 and the state transition machine 40i shares the common resource 102 in the states 96 and 99 having a group ID of 2.

According to the semiconductor integrated circuit 100c configured as shown above, the three logic circuits 101g, 101h and 101i use the common resource 102 at an interval of clocks corresponding in number to the logic circuits, that is, at an interval of three clocks in the example in FIG. 11, and therefore the common resource 102 can be used among the three logic circuits 101g, 101h and 101i without any arbitration circuit.

Furthermore, it is possible to manage the logic circuits 101a to 101i shown in FIG. 8 to FIG. 11 designed by the design apparatus 1 as an IP group, reuse the designed logic circuits 101a to 101i, freely select a combination thereof, design the aforementioned semiconductor integrated circuits 100, 100a, 100b and 100c and thereby shorten the design period.

The whole or part of the design program for executing the above described operations is recorded or stored in a portable medium such as a flexible disk, CD-ROM or a storage medium such as a hard disk as a computer program product. The program is read by a computer and the whole or part of the operations is executed. Alternatively, the whole or part of the program can be circulated or delivered via a communication network. The user can download the program via a communication network and install the program in the computer or install the program from a recording medium in the computer and thereby easily implement the design apparatus of the present embodiment.

Furthermore, steps in the flowchart of the present Specification can be executed simultaneously by changing its order of execution or executed in order which differs at each time of execution unless inconsistent with the nature thereof.

The present invention is not limited to the aforementioned embodiment, but various changes or alterations or the like can be made without departing from the spirit and scope of the present invention.

While a certain embodiment has been described, the embodiment has been presented by way of example only, and are not intended to limit the scope of the inventions. Indeed, the novel apparatuses, methods and circuits described herein may be embodied in a variety of other forms; furthermore, various omissions, substitutions and changes in the form of the apparatuses, methods and circuits described herein may be made without departing from the spirit of the inventions. The accompanying claims and their equivalents are intended to cover such forms or modifications as would fall within the scope and spirit of the inventions.

What is claimed is:

1. A design apparatus comprising:
a scheduling module configured to generate a plurality of states that transition based on a clock according to a control data flow graph from a behavioral description and common resource schedule information;
a group identifier (ID) assigning module configured to assign group IDs to the plurality of states under a predetermined condition;
a transition violation detector configured to detect whether there is any transition violation among the plurality of states corresponding with the group IDs; and
a state inserting module configured to insert a new state between states from which the transition violation has been detected, when the transition violation is detected.

2. The design apparatus of claim 1, further comprising a syntax analyzer configured to analyze a syntax of the behavioral description and to generate the control data flow graph.

3. The design apparatus of claim 2, further comprising an allocating module configured to allocate a common resource to a predetermined group ID, when no transition violation is detected.

4. The design apparatus of claim 3, further comprising a Register Transfer Level (RTL) generator configured to generate an RTL description from data obtained by the allocating module.

5. The design apparatus of claim 1, wherein the transition violation detector is configured to detect whether the state of the transition source and the state of the transition destination are associated with the same group ID in order to detect the transition violation.

6. The design apparatus of claim 1, wherein the scheduling module is configured to assign a group ID to the new state under a predetermined condition, when the new state is inserted by the state inserting module.

7. The design apparatus of claim 1, wherein the group ID assigning module is configured to assign the group IDs to the plurality of states which allows a transition from a state with a first predetermined group ID to a state with a second predetermined group ID.

8. The design apparatus of claim 1, wherein the common resource schedule information is information associated with group IDs available to be scheduled for each common resource.

9. A design method comprising:
generating a plurality of states that transition based on a clock according to a control data flow graph from a behavioral description and common resource schedule information;
assigning group IDs to the plurality of states under a predetermined condition;
detecting whether there is any transition violation among the plurality of states corresponding with the group IDs; and
inserting a new state between states from which the transition violation has been detected, when the transition violation is detected.

10. The design method of claim 9, further comprising analyzing a syntax of the behavioral description and generating the control data flow graph.

11. The design method of claim 10, further comprising allocating a common resource to a predetermined group ID, when no transition violation is detected.

12. The design method of claim 11, further comprising generating an RTL description from data obtained by allocating the common resource to the specific group ID.

13. The design method of claim 9, wherein the transition violation is detected by detecting whether the state of the transition source and the state of the transition destination are associated with the same group ID.

14. The design method of claim 9, wherein a group ID is assigned to the new state under a predetermined condition when the new state is inserted.

15. The design method of claim 9, wherein the group IDs are assigned to the plurality of states which allows a transition from a first state with a first predetermined group ID to a state with a second predetermined group ID.

16. The design method of claim 9, wherein the common resource schedule information is information associated with group IDs available to be scheduled for each common resource.

17. A semiconductor integrated circuit comprising:
a common resource; and
a plurality of logic circuits comprising states transition according to a clock, configured to execute predetermined processing and to exclusively access the common resource according to different group IDs.

18. The semiconductor integrated circuit of claim 17, wherein the plurality of logic circuits are configured to access the common resource at a clock interval of a number corresponding to the plurality of logic circuits.

19. The semiconductor integrated circuit of claim 17, wherein the plurality of logic circuits are configured to access the common resource at a clock interval of a predetermined number.

20. The semiconductor integrated circuit of claim 17, wherein the plurality of logic circuits are configured to access the common resource with different frequencies.
